(19) United States
(12) Patent Application Publication
(10) Pub. No.: US 2025/0036826 A1
(43) Pub. Date: Jan. 30, 2025

(54) System Design Process for Multi-layered Transport Networks

(71) Applicant: Honda Research Institute Europe GmbH, Offenbach/Main (DE)

(72) Inventors: Sebastian Brulin, Offenbach (DE); Ahmed Sadik, Offenbach (DE)

(73) Assignee: Honda Research Institute Europe GmbH, Offenbach/Main (DE)

(21) Appl. No.: 18/360,790

(22) Filed: Jul. 27, 2023

(51) Int. Cl. G06F 30/18

(52) U.S. Cl. CPC G06F 30/18

(57) ABSTRACT

A computer-implemented method for designing a multimodal transport network, the method comprising steps of generating an optimized transport network design by optimizing a multimodal communicability measure by adapting active edges of at least one of the layers of the transport network; and outputting the optimized transport network design.

### TECHNICAL FIELD

The disclosure relates to the general field of transport networks and urban mobility. In particular, a method and corresponding program for multimodal transportation planning in an application of spatial graph theory are proposed.

### TECHNICAL BACKGROUND

Densely populated regions face an increasing demand for fast and reliable transportation of inhabitants of the regions and goods on a limited ground area available for transportation purposes in the regions. Thus, expanding existing transport systems and designing new transport systems is a field of high importance to engineers in the field of transportation systems.

Urban Air Mobility (UAM) emerges as a promising solution to address the increasing demand for fast transportation in the densely populated regions. Integrating an additional UAM transport network into an already existing multi-layer transport network of the densely populated regions presents multiple challenges. An operator of the UAM transport network requires the planning engineers responsible for designing the UAM transport network to meet the challenge of designing a physical network structure of the UAM transport network and devising services based thereon that offers efficient and reliable transportation for passengers and goods. In order to achieve this target, the planner has to consider all (pre-) existing transport layer(s) of the transport system that already exist in the region and thereby to enable a multimodal transportation system. Adding a new transport layer to the existing transport system requires considering the robustness and efficiency of the resulting multimodal transport network including the added transport layer.

### SUMMARY

An aspect of the present disclosure concerns a computer-implemented method for designing a multimodal transport network, wherein the method comprises steps of: generating an optimized transport network design by optimizing a multimodal communicability measure by adapting active edges of at least one of the layers of the transport network; and outputting the optimized transport network design.

The proposed computer-implemented method provides a generalized process particularly suitable for integrating a new network layer within a multi-layered transport network, which achieves an improved robustness and enhanced efficiency of the resulting multimodal transport network including the new network layer.

The disclosure uses the terms transport network and transport system interchangeably.

The transport network may be a traffic network or a supply network, or integrate both a traffic network and a supply network.

A traffic network concerns transportation of persons, e.g. passengers, along routes (paths) on ground, below ground, on waterways or in air corridors above ground. Transportation may include movement of persons on foot or using physical means of transport, e.g. vehicles. Vehicles may include vehicles operated by human operators or drivers, partially autonomous vehicles and fully autonomous vehicles. Vehicles may include unmanned aerial vehicles (UAV). Physical means of transport may be public means of transport, e.g. trains, underground trains, busses, taxis, or vessels, for example. Physical means of transport may include private means of transport including bicycles, motorcycles, and cars, to name some examples.

A supply network concerns transportation of goods using means of transport as discussed with reference to the transportation of persons.

### BRIEF DESCRIPTION OF THE DRAWINGS

The aspects and implementation of the present disclosure will be explained in the following description of specific embodiments in relation to the enclosed drawings, in which:

FIG. 1 displays a block-diagram illustrating an exemplary overview of an embodiment of mobility services in a multimodal urban transport service application;

FIG. 2 shows a flowchart illustrating an overview over a multimodal network design process according to an embodiment of the method; and

FIG. 3 displays an overview over structural elements in form of a block-diagram of an implementation of a multimodal urban transport network implementing an embodiment.

The description of figures uses same references numerals for same or corresponding elements in different figures. The description of figures dispenses with a detailed discussion of same reference numerals in different figures whenever considered possible without adversely affecting comprehensibility.

### DETAILED DESCRIPTION

The computer-implemented method according to the first aspect uses the multimodal communicability measure in the process of transport network system design.

Communicability, in the context of network analysis, refers to a mathematical concept that encapsulates the ease of movement or ‘flow’ between different nodes or points within a network. Communicability and the communicability measure describing the communicability includes, but is not solely reliant on, direct connections between nodes of the network. The communicability measure includes considering a multitude of potential paths that could be taken from one (first) node to another (second) node. The communicability measure describes processes in transport networks that are generally similar to diffusion processes in other physical systems, in which particles spread out from an area (point) of higher concentration to areas of lower concentration, taking all paths that are available in the physical system.

System engineering of transport networks is an interdisciplinary field of engineering including a focus on designing, integrating and controlling operation of complex transport systems over their life cycle. The resulting transport network is a combination of technical components characteristically including hardware and software elements that work in combination to perform collectively the task of transportation. Transport systems engineering is a traditional systems engineering for products focusing on the design of physical transport systems consisting of hardware and software elements.

In a transport network, for instance, one may think of the concept of communicability as the ease with which one can move from one location to another location. The communicability measure regards not only the direct route between a start location and a destination but also considers all the other possible routes that one could take. This may include routes that involve changing lines or modes of transport, or routes that might be longer but less congested than other routes.

In essence, the communicability measure captures the overall ‘accessibility’ or ‘reachability’ between two points within a network, providing a comprehensive measure of connectivity that extends beyond just the shortest path or the most direct path. It provides a holistic view of the transport network's structure, taking into account the redundancy and diversity of paths, which is highly advantageous for analyzing the robustness and the resilience of a transport network design.

According to the disclosure, the multimodal communicability measure extends the general communicability measure. The multimodal communicability measure enables to combine routes that integrate multiple modes of transport into one single route through the transport network. Using the multimodal communicability measure in the system design process has the effect that a new transport network added to the existing transport network is designed to maximize the number of available routes on independent layers through the transport network. The multimodal communicability measure further enforces an efficient transport network design by a preference of routes that have multiple shortest paths connections between every node in the transport network. The two cited objectives ensure that a newly planned transport network layer of the new transport system provides the shortest path between two nodes while avoiding single-path routes that may easily represent a bottleneck in operations of the transport network. The multimodal communicability measure enforces a network design with an even distribution of routes (paths) within the multi-layer transport network.

Furthermore, the multimodal communicability measure takes into account the risk of cascading errors, which can occur when the transport network depends on a single mode of transport. By incentivizing paths that use multiple modes of transport and penalizing paths that require many transfers in the transport network, the multimodal communicability measure enhances the robustness of the transport system and reduces the risk of cascading errors. The approach based on the multimodal communicability measure ensures that the resulting network design is not only efficient but also robust, capable of withstanding disruptions and providing reliable service under a variety of conditions.

Using the multimodal communicability measure in the process of transport network design ensures that the new transport network added to the existing transport network in a new transportation layer maximizes a number of available routes on independent layers through the multimodal transport network in a first objective. The multimodal communicability measure enforces an efficient design by preferring routes in the communication network that have multiple shortest path connections between every node in the transport network in a second objective. The first and second objectives ensure that the newly designed transport network layer includes the shortest available path while simultaneously avoiding single-path routes that may represent bottlenecks for transportation. The first and second objectives enforce a network design with an even distribution of paths within the multi-layered transport network. The second objective in particular reduces a risk of cascading errors due to providing a reduction of the transport network interdependency and enforces the design of robust multiplex network features.

The term robustness in the field of transport systems refers to an ability of the system to perform consistently and effectively under varying operating conditions. The operating conditions may include recurring and non-recurring local events and global events, which ideally should not lead to significant disruptions to the overall transport flow in the transport network. The proposed method provides a new planning process that considers all modes of transport to find the most efficient transport network design in order to improve the transport flow in the multimodal transport system. The disclosed method utilizes in particular multi-layered design characteristics as parameters to reduce a dependency of routes on the modes of transport.

The computer-implemented method provides a design process for a multimodal transport system. The new design process represents a tool that differs from known approaches in that it allows a design engineer to address the task of planning a new transport network in a multi-layered transport system, e.g. adding a UAM network integrated with further transport systems. The new method differs from known approaches by including a multi-layered robustness as a design parameter in the network design process, while simultaneously enforcing the most efficient transport network design.

According to an embodiment of the computer-implemented method for designing a multimodal transport network, the method comprises steps of: obtaining a current state of the transport network; obtaining past congestion information of the transport network; obtaining event information on planned events in an area of the transport network; evaluating velocity information of transport movement along edges of a graph including plural layers representing the multimodal transport network based on at least the obtained current state of the transport network; predicting congestion levels for the edges of the transport network based on the obtained current state of the transport system, obtained past congestion information, obtained event information and the evaluated velocity information; computing weights for the edges based on the predicted congestion levels and associating the computed weights with the edges of the plural layers of the multimodal transport network; computing a multimodal communicability measure based on the computed weights associated with the edges of the plural layers of the multimodal transport network; generating an optimized transport network design by optimizing the multimodal communicability measure by adapting active edges of at least one of the layers of the transport network; and outputting the optimized transport network design.

The output optimized network design may include system design data that forms the basis for a product design phase for designing the transport network based on the optimized network design and a subsequent physical realization of the transport network including processes of manufacturing, procuring and controlling operations of the transport network, for example.

A particular embodiment of the computer-implemented method further comprises a step of adding a layer corresponding to an additional mode of transport to the graph of the multimodal transport network, and the method generates the optimized transport network design for the multimodal transport network including the additional mode of transport.

The computer-implemented method according to an embodiment comprises as adding the additional mode of transport adding an urban air mobility transport network to the multimodal transport network.

A mode of transport may refer to a transport network using a specific physical means of transport, e.g., an underground network, a bus network, an air taxi network. Each mode of transport defines a subnetwork of the entire multimodal transport network providing transportation for an entire region. Each subnetwork may be represented by at least one transportation layer of the graph representing the multimodal transport network.

An embodiment of the computer-implemented method comprises, in the step of generating the optimized transport network design by optimizing the multimodal communicability measure, adapting active edges of the added layer corresponding to an additional mode of transport of the transport network.

The active edges of the added layer in the graph corresponding to the additional mode of transport may be air corridors assigned to the movement of air vehicles. The attribute “active” denotes an edge, which is actually available for transportation and which is regarded during the optimization. An “inactive” edge is an edge, which is disregarded during the optimization.

The computer-implemented method according to an embodiment includes steps of receiving a planning process initiation message at predetermined time intervals during operation of the multimodal transport network, and automatically starting the process for generating the optimized transport network design when receiving the planning process initiation message.

In an embodiment, the computer-implemented method includes generating the planning process initiation message in case of determining at least one predetermined event occurs in an area served by the multimodal transport network and during operation of the multimodal transport network.

Hence, the computer-implemented method may start during operation of the multimodal transport network at regular time intervals, or irregularly, or even on determining that a demand for a rescheduling of transport services based on an amended multimodal transport network design exists. Thus, the provided optimized multimodal network design may be adapted to the acquired actual operating state of the transport system, or regards future predicted states of the transport system by respectively dynamically adapting the connections in the optimized multimodal transport network.

According to an embodiment of the computer-implemented method, the multimodal communicability measure is configured to incentivize paths that use multiple modes of transport and to penalize paths that require many transfers between different modes of transport.

Thus, a robustness of the resulting optimized transport network increases.

The computer-implemented method according to an embodiment comprises computing the multimodal communicability measure G_{pq} according to

$${G}_{pq}^{*} = \frac{1}{s !} {P}_{pq} + {\sum }_{k > s} ( \frac{1}{k !} + α \frac{{M}_{pq} - 1}{{T}_{pq} + 1} ) {W}_{pq}^{( k )} ;$$

with P_{pq} representing a number of paths of a length s between nodes p and q. W_{pq}^{(k)} denotes a weight of paths of a length k, M_{pq} is the number of different modes of transport used in the path between p and q, T_{pq} is the number of transfers along the path between p and q, and the parameter a denotes a weighting factor that controls a balance between incentivizing multimodal paths and penalizing transfers between modes of transport.

The term a (M_{pq}−1)/(T_{pq}+1) inside the sum incentivizes paths that use multiple modes of transport by increasing their weight as the number of modes of transport M_{pq} increases. Furthermore, the term penalizes paths that require many transfers by dividing by the number of transfers T_{pq}. The term is zero when there is only one mode of transport, e.g. M_{pq}=1, meaning that paths using a single mode of transport are not penalized by transfers. Thus, a robustness of the resulting transport network increases.

A second aspect of the present disclosure concerns a non-transitory computer-readable storage medium embodying a program of machine-readable instructions executable by a digital processing apparatus, wherein the program, when executed on the digital processing apparatus, causes the digital processing apparatus to perform the steps of the computer-implemented method according to the first aspect.

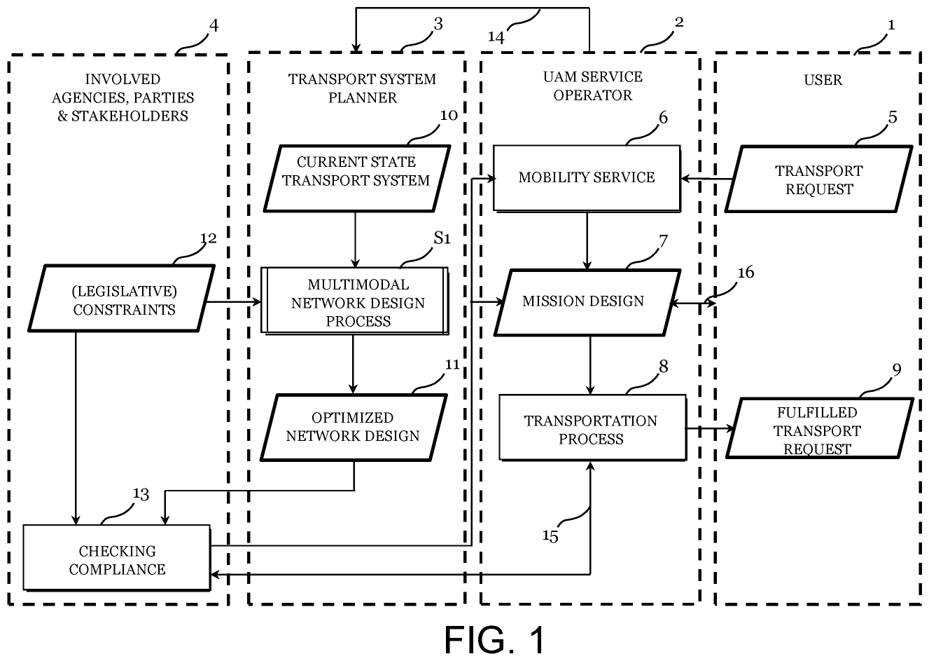

FIG. 1 displays a block-diagram illustrating an exemplary embodiment of mobility services in a multimodal urban transportation service applying an embodiment of the method in a multimodal transport network.

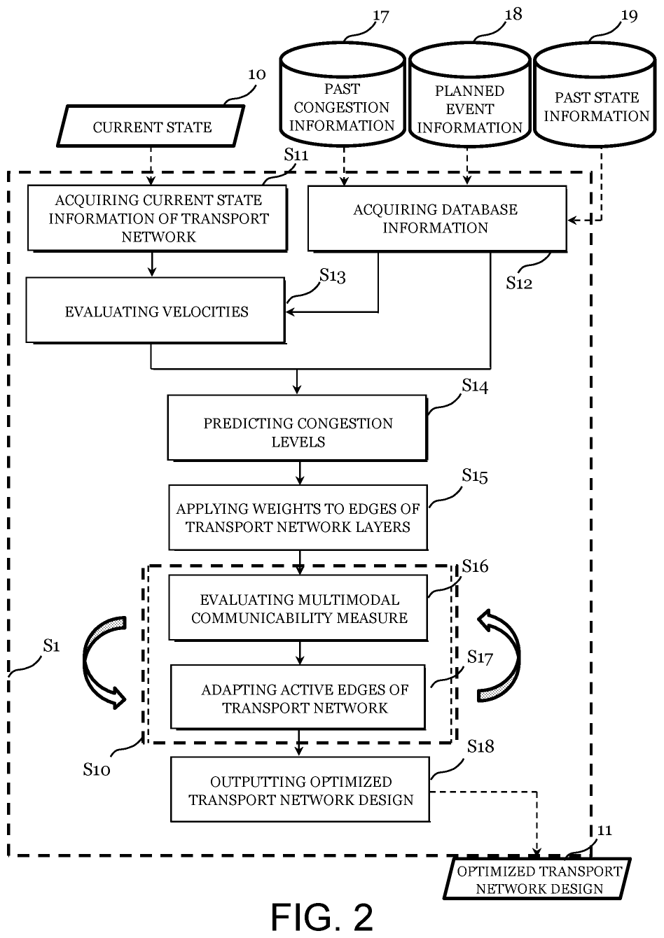

The embodiment shown in FIG. 1 concerns a high-level mobility service provision applying multimodal network design process S1 discussed in detail with reference to FIG. 2.

A service operator 2, e.g. a UAM service operator 2, may initiate the multimodal planning process as part of a design process for a new transportation layer in an a existing transport network corresponding to an existing transport system. The planning process initiation message 14 provided by the UAM service operator 2 to a transport system planner 3 may start a new network planning iteration.

The transport system planner 3 receiving the planning process initiation message 14 may be a public transport planner or a private agency transport planner, who designs a new transportation layer for the transport system. Designing a new transportation layer corresponds to addressing the technical task of generating a system design for a new transport network for a region, which already will have a pre-existing transport network.

Alternatively, the transport system planner 3 may be a same entity as a mobility service provider, e.g. the UAM service operator 2, which dynamically adapts operation of transport network connections of the multimodal transport network during operation, e.g., in order to take into account specific events scheduled to occur in the region or varying environmental conditions. The events or weather conditions may influence velocities, affect congestion levels or even general availability of connections of the transport network. Dynamically changing transport network connections based on the optimized transport network design generated based on optimizing the multimodal communicability measure may improve transport network operation in spite of adverse effects of the scheduled events or adverse weather conditions.

The transport network encompasses any representation that agents, e.g. passengers, may use for transportation in the region corresponding to an area served by the transport network. The transport network includes nodes, which represent entrance points, exit points, or transit points of the transport network. An entrance point denotes a node where a passenger or an object enters the transport network and proceeds along the edges of the transport network. An exit point denotes a node where a passenger or object exits the transport network having arrived via an edge of the transport network. A transit point is a node at which the passenger or object arrives via a first transportation layer of the transport network, switches to a second transportation layer of the transport network, and leaves via the second transportation layer of the transport network. Edges, sometimes referred as connections of the transport network connect the individual nodes of the transport network. The edges may represent streets, train tracks, navigable water channels or air corridors. A transport network design defines the topological connectivity and spatial structure of the transport network, including their spatial positions in the region and the associated transport capacity. The parameter flow capacity of an edge may describe a transport capacity of the edge or of the transport connection.

In reaction to receiving the planning process initiation message 14, the transport system planner 3 acquires current state information 10 defining the current system state of the transport system from multiple sources. The current state information 10 is configured to provide the transport system planner 3 with a complete representation of the current transport system and the various transportation layers, which the current transport system has.

The transport system planner 3 acquires the current state information 10 from different sources including, but not limited to internal databases of the transport system planner 3 and external databases accessible for the transport system planner 3 via a network N (communication network N).

The current state information may include map information of the region (environment) in which the transport system is arranged and operating. Map information includes in particular information on spatial relationships between elements relevant for transport, e.g. roads, train tracks, waterways, air traffic routes, or areas closed to air traffic available from public or private databases. Map information may also include spatial information on location of train stations, bus stations, taxi stands, airports, heliports, landing platforms, jetties, quays, harbor facilities, etc.

The current state information 10 may include information including data originating from traffic counts on connections of the transport network, traces provided by positioning systems associated with physical objects moving along connections of the transport network, e.g. traces generated by vehicle navigation systems including GNSS receivers or smart devices carried by human passengers. The current state information may include data on construction sites provided by public sources, e.g. communal authorities or road construction departments.

The transport layer planner 3 uses the acquired current state information 10 in the subsequent process, the multimodal network design process S1. The individual steps of an embodiment of the multimodal network design process S1 will be discussed with reference to the flowchart of FIG. 2 in detail. The multimodal network design process S1 has the primary objective of designing a new network layer that enhances transport efficiency, e.g. a travel time, and an overall robustness of the transport network by performing an enforced multi-layered planning process. The multi-layered planning process may be an iterative process that generates an optimized network layer design 11.

Subsequently, the generated optimized network layer design 11 may be reviewed for fulfilling general constraints 12 in a compliance check process 13. The compliance check process 13 may include evaluating the optimized transport network design 11 with regard to general constraints 12 that may include possibly time-specific constraints, such as temporary airspace closures or planned construction sites affecting the transport flow along the connections of the transport network. The general constraints 12 relevant for the multimodal network design process S1 and the optimized network design 1 may include legislative constraints or regulatory constraints in any combination.

Any involved agency 4 or stakeholders in operations of the transport network may perform the compliance check process 13 of the optimized network design 11 based on the general constraints 12.

The involved agencies 4 or stakeholders may include authorities responsible for providing public transport, maintenance of the road network, air traffic control, in order to name examples.

In an alternative embodiment to the one shown in FIG. 1, the transport system planner 3 may perform the compliance check process 13 of the optimized network design 11 based on the general constraints 12 provided by the involved agencies 4. The transport system planner 3 may adapt the optimized network design 11 in a further iteration of the multimodal network design process S1 if deemed necessary due to failing the compliance check process 13.

The compliance check process 13 may form an integral part of an embodiment of the multimodal network design process S1.

The compliance check process 13 may be executed automatically as an integral part of an embodiment of the multimodal network design process S1 based on the general constraints 12 acquired from the involved agencies 4.

After passing the compliance check process 13, the generated optimized network design 11 including at least one new designed network layer may be output to involved parties, including, but not limited to like traffic management agencies and transport operators including the UAM service operator 2 of FIG. 1.

Performing the multimodal network design process S1 for (re-) planning the transport system may be initiated by receiving the planning process initiation message 14, at predetermined time intervals and then starting the multimodal network design process S1 based on relevant parameters that may include changed congestion levels, changed weather, and predicted changed transport network loads.

The predetermined time intervals may vary with time or be time-invariant.

(Re-) planning may be triggered by generating and receiving the planning process initiation message 14 in case a predetermined event occurs. The predetermined event may include determining that a parameter exceeds a predetermined threshold. The parameter may include measured traffic congestions levels and predicted transport network loads.

The predetermined event may include a specific weather forecast, or an imminent event that typically results in increased levels of traffic or reduced capacity on at least one transport connection.

If passing the compliance check process 13, the mobility service provider, in the example of FIG. 1 the UAM service operator 2 may integrate the new designed network layer into the services the mobility service provider offers to users 1.

When a user 1 intends to move in the region served by the multimodal transport network using the transport system, the user 1 issues a transport service request 5 and transmits the issued transport request 5 to the UAM service operator 2. The UAM service operator 2 processes the received transport request 5 by executing a mobility service process 6. Executing the mobility service process is based on the received transport request 5 and the optimized transport network design 11, which has successfully passed the compliance check process 13 and has been provided from the transport system planer 3 to the UAM service operator 2. The UAM service operator 2 generates a mission design 7 based on the mobility service process 6, that bases on the optimized transport network design 11 as approved in the compliance check process 13.

The UAM service operator 2 generates the mission design 7 in form of mission design information that includes information on at least one assigned vehicle, e.g. an air taxi, in response to the transport request 5 and transport route information that defines a movement route along the edges of the optimized transport network design. The mission design information may include transport times, including transport departure times (start times), change times for changing a mode of transport, arrival times (end times) for an arrival at a target destination of the transport request 5.

The mission design information may include change information concerning a change of the mode of transport, e.g. including which mode of transport where and when to change during the transport.

While executing the mobility service process 6 for planning the transport task requested by the user 1, and for generating the transport mission design 7 in response to the transport request 5, the UAM service provider 2 may communicate further information 16 to the user 1 and receive further information from the user 1.

During mobility service process 6, and for generating the mission design 7, updated information from third parties about changes to the local area served by the transport system may be required. The UAM service provider 2 acquires such further information 16 from the user 1 and further information 15 from other stakeholders and the involved agencies 4 in the transport system and in the services provided by the transport system.

Acquiring further information 15, 16 may be performed via a bidirectional communication between the UAM service operator 2, the user 1 and the involved agencies, involved agencies 4 or stakeholders.

The UAM service provider 2 transfers the generated mission design 7 to the transportation process 8. The transportation process 8 includes the transport system executing the requested transport task defined in the transport request 5 based on the generated transport mission 7.

Once the transport process is successfully executed, the transport request 5 issued by the user 1 is fulfilled, and a respective fulfilled transport request 9 may be signaled by the UAM service operator 2.

FIG. 2 shows a flowchart illustrating an overview over a multimodal network design process S1 according to an embodiment of the computer-implemented method.

The flowchart of FIG. 2 illustrates an embodiment of the computer-implemented method that generates an optimized network design 11 for the transport system and outputs the generated optimized network design 11 for further processing.

The computer-implemented method includes obtaining a current state 10 of the multimodal transport network, obtaining past congestion information of the transport network, obtaining (planned) event information on planned events in an area (served region) of the multimodal transport network.

The computer-implemented method may include obtaining a past state of the multimodal transport network.

The multimodal network design process S1 starts with acquiring current state information 10 on the transport network in step S11 from a plurality of databases.

The database information acquired in step S12 of FIG. 2 comprises past congestion information including information on transport congestions (traffic jams) on the edges of the transport network from a first database 17.

The database information acquired in step S12 of FIG. 2 comprises planned event information including on planned events in the area served by the transport system resp. the transport network from a second database 18.

The database information acquired in step S12 of FIG. 2 further comprises past state information including information on previous states of the transport system from a third database 19.

The multimodal network design process S1 may execute steps S11 and S12 in parallel or sequentially.

In a step S13 following steps S11 and S12, the multimodal network design process S1 continues with evaluating the velocities on each edge of the transport system based on the information in the acquired current state information of the transport system.

Step S13 includes evaluating velocity information of moving physical objects or users (passengers) moving along edges of a graph including plural layers representing the multimodal transport network based on at least the obtained current state of the transport network.

In particular, the velocities on each edge are evaluated for all existing layers of the transport network.

In particular, in step S13, velocities of objects, in particular vehicles, moving persons or transported goods on the edges of the transport network included in the current state information are compared with past information, in particular past state information obtained in step S12. Evaluating velocities includes determining (measuring) current velocities and predicting (estimating) future velocities of the objects or moving persons.

In subsequent step S14, the multimodal network design process S1 proceeds with predicting congestion levels for the edges of the transport network, e.g. using a time series prediction based on the knowledge about past and future events included in the planned event information and the predicted velocities from step S13. Predicting a time series of congestion levels on the edges may use models to predict sequences of discrete-time data including future values based on previously observed or predicted values using time series forecasting.

Predicting the congestion levels for the edges of the transport network bases on the obtained current state of the transport system, the obtained past congestion information, the obtained event information and the evaluated velocity information from step S14.

Based on the predicted congestion levels of prediction step S14, the multimodal network design process S1 computes edge weights based on the measured velocities and the predicted velocities in step S15. The multimodal network design process S1 associates the computed weights with the edges of the plural layers of the multimodal transport network. The multimodal network design process S1 updates the weights of the edges in the existing layers of the transport system based on the computed edge weights.

FIG. 2 shows steps S14 and S15 as distinct steps executed successively. Steps S14 and S15 may be combined in one integrated step.

The multimodal network design process S1 then proceeds with an optimization loop S10, which in the embodiment FIG. 2 shows to include steps S16 and S17. In the optimization loop, a multimodal communicability measure is applied to the weighted transport network including weighted edges in order to design a new network layer for the transport network.

The optimization loop S10 includes computing the multimodal communicability measure based on the computed weights associated with the edges of the plural layers of the multimodal transport network. In particular, the optimization loop S10 includes maximizing the multimodal communicability measure.

The multimodal communicability measure used in the multimodal network design process S1 bases on a most direct connection between two nodes of the transport network. The most direct connection between two nodes of the transport network may be understood as the communicability within the transport network.

The approach based on the multimodal communicability measure allows to apply the concept of communicability in the context of multimodal transport networks, and to extend communicability to incorporate the diversity of modes of transport available for different paths. The multimodal communicability measure G_{pq} incentivizes paths that use multiple modes of transport and penalizes paths that require many transfers, thereby enhancing the robustness of the transportation system:

$${G}_{pq}^{*} = \frac{1}{s !} {P}_{pq} + {\sum }_{k > s} ( \frac{1}{k !} + α \frac{{M}_{pq} - 1}{{T}_{pq} + 1} ) {W}_{pq}^{( k )} ; \qquad ( 1 )$$

In formula (1), P_{pq} represents the number of paths of a length s between nodes p and q. W_{pq}^{(k)} denotes the weight of paths of length k. M_{pq} is the number of different modes of transport used in the path between p and q. T_{pq} is the number of transfers along the path between p and q.

The parameter a is a weighting factor that controls the balance between incentivizing multimodal paths and penalizing transfers.

In formula (1), the term a (M_{pq}−1)/(T_{pq}+1) inside the sum serves two purposes. First, the term incentivizes paths that use multiple modes of transport by increasing their weight as the number of modes of transport M_{pq} increases. Second, the term penalizes paths that require many transfers by dividing by the number of transfers T_{pq}. The term is zero when there is only one mode of transport, e.g. M_{pq}=1, meaning that paths using a single mode of transport are not penalized by transfers.

An operator designing a transport service can leverage the multimodal communicability measure to optimize the efficiency and robustness of the service. For example, the operator planning a new bus route in a city that already has a well-established tram and subway network. The operator may use the multimodal communicability measure to identify the most efficient paths for the new bus route that complement the existing paths provided by the tram and subway networks.

For instance, instead of duplicating a popular subway route, a new bus route could be designed to connect areas that are not well-served by the existing subway or tram lines. This would increase the overall multimodal communicability of the transport network, providing more efficient travel options for commuters and reducing congestion on routes provided by the subway and tram networks.

Furthermore, in the event of disruptions on the transport network, e.g. a subway line closure or tram breakdown, the operator can quickly identify alternative bus routes that maintain connectivity and service reliability over the multimodal transport network. By considering multimodal communicability in the planning and operation of the transport service, the operator can ensure that the service provided by the technical means of transport is not only efficient but also robust to potential disruptions.

The defined multimodal communicability measure may not guarantee communicability between those nodes in transport networks that have capacity constraints or a potential failure of edges between nodes. The optimization loop S10 of the multimodal network design process S1 may employ a more general communicability measure that considers all available paths of the transport network but decreases contributions of longer paths instead. The proposed multi-layered communicability of the present disclosure utilizes information about the independence of the separate layers of the transport network. It increases the contribution of paths from other layers of the transport network compared to a shortest path modal chain. The multimodal communicability measure identifies modal bottlenecks in the multimodal transport network and designs the new transport layer to find the optimal network layout that improves multimodal communicability, transportation efficiency, and robustness of the full transport network by reducing the effects of edge failures on the overall transportation process.

The optimization loop includes evaluating the multimodal communicability measure and comparing the evaluated multimodal communicability measure (optimization parameter) with a convergence criterion in step S16. In step S17 that follows step S16 in case the convergence criterion is not yet met, active edges (e.g. active corridors) in the transport layers are adapted and a new cycle of the optimization loop is started with the processing to step S16 again.

Adapting active edges may include amending at least one edge, or at least one node of a graph representing the multimodal transport network.

Adapting active edges includes varying at least one parameter, e.g. a transport capacity, of at least one edge, or at least one node, or a structural topology of the graph representing the multimodal transport network.

In case the optimization parameter meets the convergence criterion, the optimization loop S10 converges, and no other transport network designs that improve the multimodal communicability measure are found, the multimodal network design process S1 terminates the optimization loop S10. The optimized transport network layer is subsequently checked for consistency. In case consistency is attributed to the optimized transport network layer(s) may be added to the optimized transport network design 10 of the transport system.

Step S18 then includes outputting the optimized transport network design. The output optimized transport network design of the multimodal transport network may then be stored in a database.

The stored optimized transport network design may form the basis for the system design of adding a new transport layer implementing an additional mode of transport to the multimodal transport system in the region. For example, an additional UAM transport system may be physically implemented in the region based on the optimized transport network design.

The stored optimized transport network design may form the basis for operating a new transport layer implementing a transport service with an additional mode of transport integrated with the multimodal transport system in the region. For example, the additional UAM transport system and its active flight corridors may be operated in the region based on the optimized transport network design.

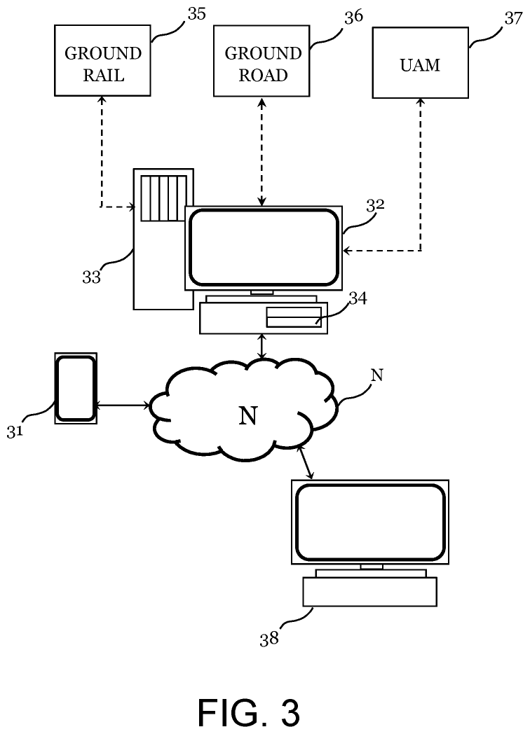

FIG. 3 displays an overview over structural elements and devices in form of a block-diagram of an implementation of a multimodal urban transport system.

At least one or all the processes and processing steps discussed above with reference to FIGS. 1 and 2 may be performed by computing means including at least one processing unit and associated memory. FIG. 3 illustrates an exemplary system structure for implementing the disclosed computer-implemented method.

The system may include at least one computing device 32, which may be a personal computer or any other computing device known in the art. The at least one computing device 32 may include one or more processing units (processors) and a memory that are configured to run an automated program implementing the disclosed method. The at least one computing device 32 may communicate via wireless or wired connections with at least one database 32 implemented on a server 33. The server 33 may itself be implemented using a computing device different from the at least one computing device 32, or be incorporated into the at least one computing device 32.

The server 33 may in particular implement the first database 17, the second database 18 and the third database 19. FIG. 3 displays the server 33 co-located with the computing device 32. Alternatively, the server 33 may communicate wirelessly or via wired connection with the computing device 32 via the network N.

The network may be an IP-based communication network.

The computing device 32 may further comprise a non-transitory machine-readable data storage medium 34, which may be physically arranged within the at least one computing device 32, or within the server device 33.

The non-transitory machine-readable data storage medium 34 may in particular store machine-readable instructions of a program that when executed on the processor of the computing device 32 results in the computing device 32 performing the steps of the disclosed method.

The computing device 32 includes data interfaces to a rail transport system 35, a road transport system 36 and UAM transport system 37, which together implement a multimodal transport network (system) extending over a commonly served area and providing transport services for at least one of goods (objects) and passengers. Via the data interfaces of the computing device 32, the computing device 32 may acquire data including current state information of the rail transport system 35, the road transport system 36 and the UAM transport system 37.

The computing device 32 may be configured to perform the steps of FIGS. 1 and 2 automatically or autonomously without human intervention by an operator once the required input data has been acquired.

The required input data may include a transport request 5 input by the user 1 via a user terminal 31. The user terminal 31 may be implemented via an application program (transport app) providing a graphical user interface (GUI) for communication with the user 1. The user terminal 31 is linked with the computing device 32 via the network N. In FIG. 3 the user 1 may obtain data defining a transport mission design 7 from the UAM service operator 2 via the GUI running on the user terminal 31.

At least one further computing device 38 is linked with the at least one computing device 32 via a network N. The further computing device 38 may be configured to enable other involved agencies 4, parties and stakeholders to provide constraints of any kind to the multimodal network design process S1. The further computing device 38 may also enable to perform a compliance check process 13 on an optimized transport network 11.

Each of the at least one first computing device 32 and the further computing device 38 may include display means for presenting visual information to humans and input means such as keyboards, microphones, or pointing devices.

The disclosure described enables to utilize a multimodal, computer-implemented planning method for application in planning or optimizing a transport network. The method considers all inter-modal transportation possibilities in the design process for the transport network. The method improves the robustness of the entire transport network and leads to a more efficient and reliable transport network.

The design process for the transport network may comprise a redesign of an existing multimodal transportation system that bases on at least one change in a design parameter.

Additionally or alternatively, the design process for the transport system may include designing an entire new, multimodal transport network.

Additionally or alternatively, the design process for the transport network may include adding and designing an additional mode of transport to an existing, possibly multimodal transport network. This may in include the particular embodiment of integrating an UAM transport network to an existing urban multimodal transport network.

The disclosed method offers a wide range of technical applications in the field of transport systems and in particular in the area of system engineering of transport systems, and hence is susceptible to advantageous commercial applications.

A potential application of this disclosure is in the technical area of city planning and transportation planning for built-up areas. Engineering firms and transportation companies designing new transport services may apply the method as integral part of the design process. By using the multimodal planning method, the design engineer may ensure that the UAM network is integrated into the already existing transport network, resulting in a more balanced transport load and reducing congestion over the resulting multimodal transport network. The result are improved transport services for residents and commuters of the area.

A further advantageous application of the method concerns operating the mobility services, as the disclosed process may be used to dynamically adapt the processes of mission design of the offered transport services to load changes. Load changes on the transport system may occur due to recurring and non-recurring events on at least one of a local scale, regional scale and global scale with regard to the transport system. Such events may include traffic accidents, road closures, lane blockings, and construction sites. Further examples for events include weather conditions, in particular adverse weather conditions, such as rain, snow, fog, thunderstorms. Integrating the method within operations of the multimodal transport system reduces the likelihood of major disruptions in transport services by improving the transport flow over the multimodal transport system by offering redundancies.

The disclosure uses terminology commonly used in network technology and transport system. For sake of convenience, a short summary of the used nomenclature is attached:

The term interdependent networks denotes networks that require the proper functioning of other networks in order to function themselves as intended.

Multiplex networks are networks that include multiple layers, wherein the multiple layers represent different types of connections between nodes or different types of interactions.

Multi-layer networks (multilayer networks) are networks, which include multiple layers representing different levels of a system, e.g. a transport system.

The expression urban air mobility (UAM) denotes a transport system that employs air vehicles as means for transportation over short distances within urban areas. UAM may provide at least one of passenger transportation and transportation of objects in an urban environment.

The term robustness characterizes generally an ability of a system, e.g. in present disclosure the transport system, to perform consistently and effectively under different and operating conditions, including coping with unexpected events in the environment of the system without causing major disruptions to the overall system function, e.g. a transport flow.

The term multimodal communicability measure denotes a measure that is used to optimize the transport flow across different modes of transport. The multimodal communicability measure achieves distribution of transport paths through the transport network that achieve a balanced transport load over the nodes and connections of the transport network.

### Further Definitions:

Multimodal transport, multimodal transport sometimes known as combined transport concerns transport of goods and persons under a single contract in one transport mission, but performs the actual transport with at least two different modes of transport. The transport carrier providing the transport service is liable for the entire transport mission, although several different modes of transport are used to physically implement the transport mission, e.g. by rail, air and road, for example for portions of the respective transport path. The transport carrier does not necessarily possess all the means of transport for implementing the transport mission. The carrier responsible for the entire transport mission is often referred as a multimodal transport operator (MTO), wherein sub-carriers, or referred to in legal language as actual carriers, perform parts of the transport mission along respective path segments of the transport path.

Intermodal passenger transport is sometimes referenced as mixed-mode commuting involving two or more modes of transport in a single journey.

In the context of multimodal transport systems and their mathematical representation, a transportation layer is defined as a distinct subgraph within the transportation network graph. In mathematical terms, a transportation layer can be viewed as a subset of the nodes and edges of the graph that form a subgraph. This subgraph represents a particular mode of transport in a multimodal transport system. Each transportation layer, therefore, encapsulates the structure and connectivity of one mode of transport within the larger multimodal network Transportation layer: a transportation layer comprises nodes and edges. The disclosure proposes to design a new transportation layer in an existing transport network, focusing on identifying the bottlenecks of the existing transport system and designing a new transportation layer to increase the overall robustness of the system.

A transportation network graph of a multimodal transport system is a mathematical representation of the structure of the transport network. The graph is composed of nodes, which represent specific locations or points within the transport network, and edges, which represent the traversable connections or paths between these locations. Each node interconnects two edges or is a transportation link start or a transportation link end. Each edge of the graph signifies a path that supports a specific mode of transport, with the characteristics of the path represented as attributes or weights associated with the edge. Each edge connects two nodes. Each mode of transport can be represented as a separate layer within the graph, with its own sets of nodes and edges. Applying various graph theory algorithms and measures on the transportation network graph enables to analyze and optimize the physical transport network corresponding to the graph.

Transport request: demand for transportation of a passenger or a good between a pair of nodes, each pair of nodes being interconnected by routes, each route being a respective sequence of transportation links. Each route is associated with respective route transportation cost. Each transportation link has an associated transportation capacity. Each link may be assigned with a transportation traffic flow.

A weight is assigned to each edge of the transport network or transportation link. Generating a graph including nodes and edges representing the transport network. Annotating the graph with a weight to each edge based on data associated with the edge. Generating an annotated graph by assigning weights to edges based on data associated with the transportation link represented by the edges.

The present disclosure relates to a process for evaluating and optimizing a transport network for robustness employing a graph. A graph is a collection of nodes (vertices) and edges connecting the nodes as employed to model a network. Every edge has two endpoints in the set of nodes, and the edge connects or joins the two endpoints. A set of two vertices may thus define an edge. The vertex set of a graph G is usually denoted by V (G). An order of the graph G corresponds to the number of its vertices, e.g. |V (G)|. A size of a graph is the number of the edges of the graph. Two vertices are adjacent vertices in case an edge exists between the vertices. The communicability between a pair of nodes in the transport network may be considered as the shortest path between the pair of nodes.

What is claimed is:

1. A computer-implemented method for designing a multimodal transport network, the method comprising steps of:
generating an optimized transport network design by optimizing a multimodal communicability measure by adapting active edges of at least one of layers of the transport network; and
outputting the optimized transport network design.

2. The computer-implemented method according to claim 1, further comprising steps of:
obtaining a current state of the transport network;
obtaining past congestion information of the transport network;
obtaining event information on planned events in an area of the transport network;
evaluating velocity information of transport movement along edges of a graph including plural layers representing the multimodal transport network based on at least the obtained current state of the transport network;
predicting congestion levels for the edges of the transport network based on the obtained current state of the transport system, the obtained past congestion information, the obtained event information and the evaluated velocity information;
computing weights for the edges based on the predicted congestion levels and associating the computed weights with the edges of the plural layers of the multimodal transport network; and
computing the multimodal communicability measure based on the computed weights associated with the edges of the plural layers of the multimodal transport network.

3. The computer-implemented method according to claim 2, wherein the method further comprises a step of
adding a layer based on an additional mode of transport to the graph of the multimodal transport network, and
generating the optimized transport network design for the multimodal transport network including the added layer based on the additional mode of transport.

4. The computer-implemented method according to claim 3, wherein
the added layer based on the additional mode of transport adds an urban air mobility transport network to the multimodal transport network.

5. The computer-implemented method according to claim 3, wherein
in the step of generating the optimized transport network design by optimizing the multimodal communicability measure, active edges of the added layer based on the additional mode of transport are adapted.

6. The computer-implemented method according to claim 2, wherein the method comprises
receiving a planning process initiation message at predetermined time intervals during operation of the multimodal transport network, and
automatically starting generating the optimized transport network design when receiving the planning process initiation message.

7. The computer-implemented method according to claim 1, wherein
the multimodal communicability measure is configured to incentivize paths that use multiple modes of transport and to penalize paths that require many transfers between different modes of transport.

8. The computer-implemented method according to claim 1, wherein the method comprises
computing the multimodal communicability measure G_{pq} based on
$${G}_{pq}^{*} = \frac{1}{s !} {P}_{pq} + {\sum }_{k > s} ( \frac{1}{k !} + α \frac{{M}_{pq} - 1}{{T}_{pq} + 1} ) {W}_{pq}^{( k )} ;$$
with P_{pq} representing a number of paths of a length s between nodes p and q, w_{pq}^{(k)} denoting a weight of paths of a length k, M_{pq} is a number of different modes of transport used in the path between the nodes p and q, T_{pq} is a number of transfers along the path between the nodes p and q, parameter a denoting a weighting factor that controls a balance between incentivizing multimodal paths and penalizing transfers.

9. A non-transitory computer-readable storage medium embodying a program of machine-readable instructions executable by a digital processing apparatus, wherein the program, when executed on the digital processing apparatus, causes the digital processing apparatus to perform the steps according to claim 1.
